(19) United States
(12) Patent Application Publication
(10) Pub. No.: US 2005/0134857 A1
(43) Pub. Date: Jun. 23, 2005

(54) Method to monitor silicide formation on product wafers

(75) Inventors: Alvaro Maury, Singapore (SG); Nace Layadi, Singapore (SG); Jovin Lim, Singapore (SG)

Correspondence Address: STEPHEN B. ACKERMAN, 28 DAVIS AVENUE, POUGHKEEPSIE, NY, 12603, US

(73) Assignee: Chartered Semiconductor Manufacturing Ltd.

(21) Appl. No.: 10/742,986

(22) Filed: Dec. 22, 2003

(51) Int. Cl. H01L 21/66; G01R 31/26; G01N 21/00

(52) U.S. Cl. 356/432

(57) ABSTRACT

A new method to monitor sheet resistance of a metal silicide layer in the manufacture of an integrated circuit device is achieved. The method comprises providing a metal silicide layer overlying an exposed silicon layer on a substrate. A thermal wave intensity signal is generated for the metal silicide layer by an optical measurement system. The optical measurement system comprises a first laser beam that is intensity modulated and a second laser beam. The first and second laser beams comprise different wavelengths. A dichroic mirror is used to combine the first and second laser beams and to project the first and second laser beams onto the metal silicide layer. A detector is used to gather the second laser beam reflected from the metal silicide layer and to generate a thermal wave intensity signal based on the reflected second laser beam. Sheet resistance of the metal silicide layer is calculated by a linear equation based on the thermal wave intensity signal.

### BACKGROUND OF THE INVENTION

1. Field of the Invention

The invention relates to a method of manufacturing an integrated circuit device, and, more particularly, to a method of monitoring silicide formation.

2. Description of the Prior Art

Metal silicide thin films are frequently used in the art of integrated circuit manufacturing. Metal silicide provides a means to reduce the resistance of gate, source, and drain regions in MOS devices. A typical metal silicide application is shown in FIGS. 1 through 3. Referring particularly to FIG. 1, a cross section of a partially completed integrated circuit device is illustrated. MOS transistors are formed on a silicon substrate 10. Each transistor comprises a polysilicon layer 22 overlying an oxide layer 18 to form a gate and heavily doped source and drain regions 14. In addition, dielectric spacers 26 are formed on the sidewalls of the gates 22 as part of the lightly doped drain process that is well known in the art. These spacers also can be used to facilitate formation of a self-aligned silicide as is shown in FIGS. 2 and 3.

Referring particularly to FIG. 2, a metal layer 30 is deposited overlying the substrate 10 and the MOS devices. A thermal process is then performed to catalyze the reaction of the metal layer 30 and the exposed silicon of the source and drain regions 14 and of the polysilicon gate 22. The reaction results in a metal silicide layer 34 forming on the source and drain regions 14 and on the polysilicon gate 22. The unreacted metal layer 30 is then removed. Since the metal layer 30 does not react with the dielectric layers, metal silicide 34 is not formed on the shallow trench isolation (STI) region 12 or on the spacers 26. Therefore, the metal silicide layer 34 is formed self-aligned to the gate 22 and source/drain regions 14 without a masking process and is, therefore, typically called a self-aligned silicide or salicide.

In the manufacturing process, this metal silicide step is quality monitored. This monitoring has typically been by measuring the sheet resistance (ohms/square) of the metal silicide. Referring now to FIG. 4, an exemplary technique to monitor the metal silicide is shown. In this technique, a four point probe is performed. In the example case, a metal silicide film 54 is formed overlying a silicon wafer 50. The metal silicide film 54 is directly probed 58a-58d. A current I 66 is forced through two probes 58a and 58d while a volt meter (V.M) 62 is used to monitor the voltage at two other probes 58b and 58c. As a result, the resistance is measured. The measurement is configured such that a square area of film 54 conducts the current. Therefore, the resistance value is per square and is called the sheet resistance of the film 54.

In practice, it is necessary to use a monitor wafer to obtain the metal silicide sheet resistance data. Referring now to FIG. 5, a lot 70 of product wafers are typically processed through the manufacturing sequence at the same time. During the metal silicide process steps, a monitor wafer 74 is added to the lot 70. A metal silicide layer is formed conformally over this monitor wafer 74 at the same time it is formed at the source/drain and gate sights on the product wafers 70. The monitor wafer 70, and not the product wafers 74, is then measured by direct probing to derive a sheet resistance value. This approach has several disadvantages. First, one product wafer is lost per batch 70 processed due to the need to make room for the monitor wafer 74. Second, the sheet resistance measurements of the monitors are obscured by batch-to-batch variations, particularly after the deposition of titanium and/or titanium nitride and the first rapid thermal anneal (RTA) process. Therefore, the present method of metal silicide monitoring is expensive and generates less than optimal results.

Several prior art inventions relate to methods of measuring integrated circuit thin films. U.S. Pat. No. 4,679,946 to Rosenwaig et al shows an apparatus to measure thickness and thermal conductivity of thin films. The apparatus comprises a source, or heating, laser that is intensity modulated and a probe laser. The source laser and probe laser are of different wavelengths. A dichroic mirror is used to combine the source and probe beams and to project them onto the substrate. A method to measure thickness and thermal conductivity is described. U.S. Pat. No. 6,532,070 to Hovinen et al shows an apparatus and a method to measure ion concentration and energy profiles on a semiconductor wafer. The apparatus shows a pump laser beam that is intensity modulated. A probe laser beam is combined with the pump laser beam by a dichroic mirror. U.S. Pat. No. 6,608,689 to Wei et al shows an apparatus and a method to measure thin film stress and thickness using laser light. U.S. Pat. No. 5,228,776 to Smith et al shows an apparatus and a method to evaluate the electrical integrity of metal lines and vias. The invention uses a system comprising an intensity modulated, pump laser beam, a probe laser beam, and a dichroic mirror. U.S. Pat. No. 6,633,367 to Gogolla shows a method and a device for optoelectronic distance measurement using an intensity modulated laser beam. U.S. Pat. No. 6,11,638 to Chou et al describes using diode lasers to detect defects in a solar cell. U.S. Pat. No. 6,622,059 to Toprac et al discloses automated process monitoring including sheet resistance and silicide measurement. U.S. Pat. No. 5,844,684 to Maris et al shows using pump and probe optical beams for non-destructive evaluation of materials including silicide monitoring of phase and thickness. One embodiment includes a dichroic mirror. U.S. Patent Application No. 2003/0164946 to Borden et al uses two laser beams to measure sheet resistance of a silicide layer. U.S. Patent Application No. 2003/0060092 to Johnson et al discloses using two probes two measure sheet resistance of a silicide layer.

### SUMMARY OF THE INVENTION

A principal object of the present invention is to provide an effective and very manufacturable method to monitor a metal silicide process in an integrated circuit device.

A further object of the present invention is to provide a method that eliminates the need for using monitoring wafers.

A yet further object of the present invention is to provide a method that provides metal silicide sheet resistance data directly from production wafers.

A yet further object of the present invention is to provide a sheet resistance measurement that more accurately reflects processing results on the production wafers.

A yet further object of the present invention is to provide a method of measurement that does not lead to quality losses due to direct probing damage.

A yet further object of the present invention is to provide a method of measurement that can be easily incorporated into a statistical processing control (SPC) system.

In accordance with the objects of this invention, a method to monitor sheet resistance of a metal silicide layer in the manufacture of an integrated circuit device is achieved. The method comprises providing a metal silicide layer overlying an exposed silicon layer on a substrate. A thermal wave intensity signal is generated for the metal silicide layer by an optical measurement system. The optical measurement system comprises a first laser beam that is intensity modulated and a second laser beam. The first and second laser beams comprise different wavelengths. A dichroic mirror is used to combine the first and second laser beams and to project the first and second laser beams onto the metal silicide layer. A detector is used to gather the second laser beam reflected from the metal silicide layer and to generate a thermal wave intensity signal based on the reflected second laser beam. Sheet resistance of the metal silicide layer is calculated by a linear equation based on the thermal wave intensity signal.

### BRIEF DESCRIPTION OF THE DRAWINGS

In the accompanying drawings forming a material part of this description, there is shown:

FIGS. 1 through 3 illustrate an exemplary metal silicide process in cross sectional representation.

FIG. 4 illustrates a direct probing technique to measure sheet resistance of a thin film.

FIG. 5 illustrates the use of a monitor wafer to measure metal silicide sheet resistance.

FIGS. 6 and 10 illustrate a preferred embodiment of the present invention.

FIGS. 7a-7c, 8a-8c, and 9a-9c illustrate three embodiments of the measurement structure of the present invention.

FIGS. 11 and 12 illustrate thermal wave intensity data and sheet resistance data measured before and after the thermal anneal process.

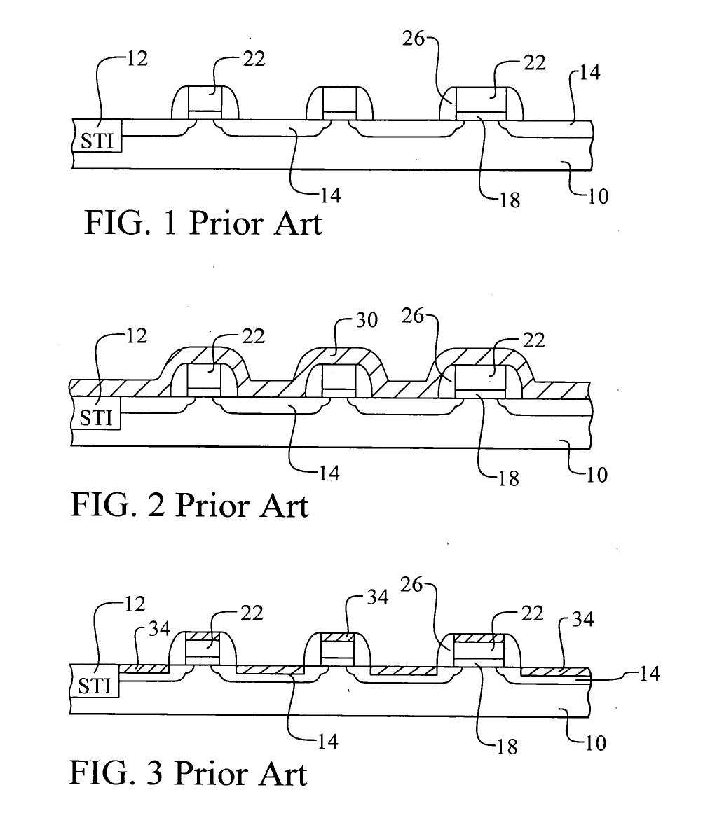

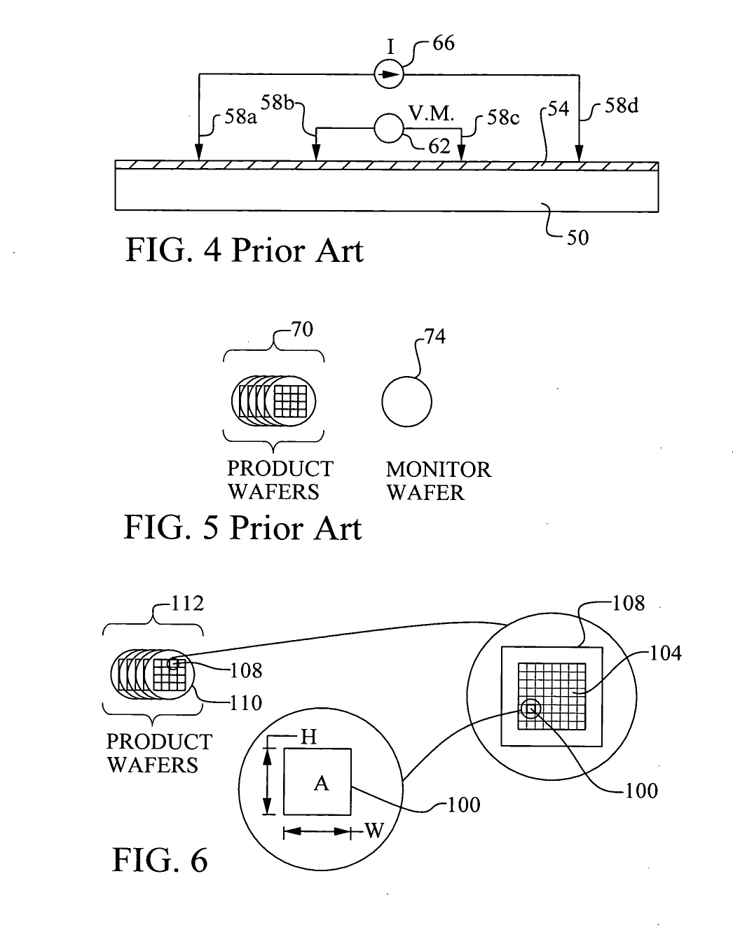

### DESCRIPTION OF THE PREFERRED EMBODIMENTS

The preferred embodiments of the present invention disclose a method to monitor the metal silicide process in the manufacture of an integrated circuit device. An optical measurement system is used to derive an electronic signal from product wafers. This electronic signal linearly corresponds to sheet resistance and is used in the present invention as a means of monitoring the metal silicide process. It should be clear to those experienced in the art that the present invention can be applied and extended without deviating from the scope of the present invention.

FIGS. 6 through 10 illustrate the preferred embodiment of the present invention. Several important features of the present invention are shown and discussed below. Referring particularly to FIG. 6, a new method for monitoring metal silicide sheet resistance is shown. In this method, the measurement is performed via an optical measuring system that measures the sheet resistance on the product wafers 112. Each product wafer 110 comprises a semiconductor substrate and, more preferably, comprise silicon. Each product wafer 110 further comprises a plurality of integrated circuits 108. On a typical wafer 110, hundreds, or thousands, of circuit die 108 are formed as is well known in the art. As an important feature of the present invention, a silicide test pad 100 is formed somewhere on the integrated circuit wafer 110. For example, the silicide test pad 100 may be designed into integrated circuit die 108 as shown. Alternatively, the silicide test pad 100 may be formed on a special test die on the wafer 110. Most importantly, the method does not require a separate monitoring wafer.

The silicide test pad 100 comprises an exposed silicon region. For example the silicide test pad 100 may comprise an area of the silicon substrate that is exposed to the silicide processing sequence. Alternatively, the silicide test pad 100 may comprise an area of polysilicon that is exposed to the silicide processing sequence. It is further found that the silicide test pad 100 should comprise a minimum dimension of about 50 μm in height H and about 50 μm in width W or a minimum area (A) of about 2500 μm². Smaller silicide test pad areas (A) may result in anomalies in the thermal wave measurement method described below.

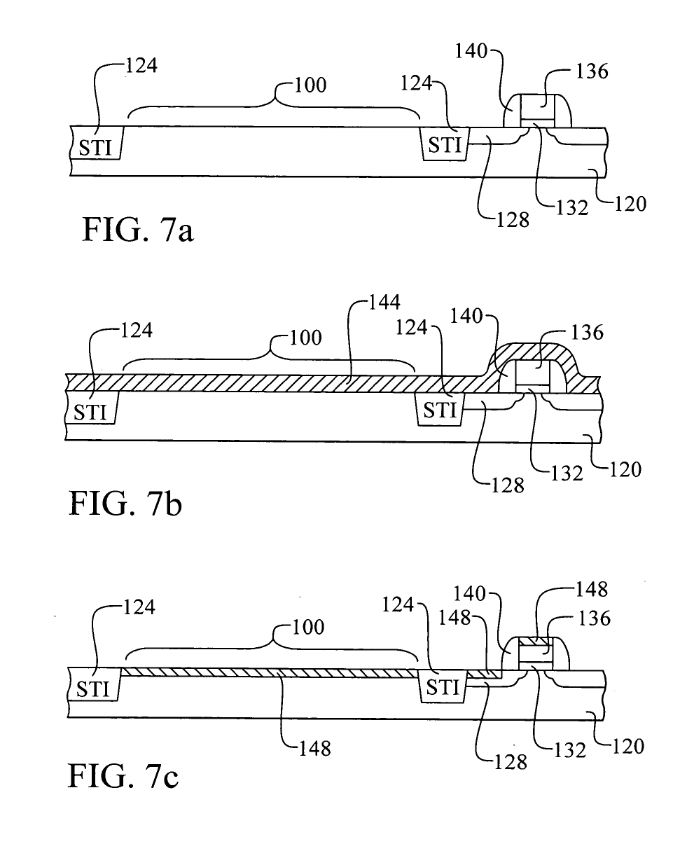

Referring now to FIGS. 7a-7c, 8a-8c, and 9a-9c, alternative embodiments of the silicide test pad 100 are illustrated in cross sectional representation. Referring particularly to FIG. 7a, a silicide test pad comprising bare silicon is illustrated. The substrate 120 preferably comprises silicon and, more preferably, comprises monocrystalline silicon. The substrate 120 is preferably lightly doped with an ionic species such as phosphorus or boron as is well known in the art. At this point in the manufacturing process, the transistor devices are formed. For example, the gates comprise a polysilicon layer 136 overlying an oxide layer 132. Source and drain regions 128 are formed in the substrate 120 by ion implantation. Dielectric spacers 140 may be formed on the sidewalls of the gates 136. The silicide test pad region 100 is preferably bounded by isolation regions 124 and, more preferably, bounded by shallow trench isolations 124 comprising a dielectric layer in a trench. In this way, the subsequently formed metal silicide film at the silicide test pad 100 does not interfere with the function of other integrated circuit devices.

Referring now to FIG. 7b, a metal layer 144 is formed overlying the exposed silicon 120. The metal layer 144 comprises a metal that will react with the silicon to form metal silicide. For example, titanium, cobalt, or nickel may be used for the metal layer 144. The metal layer 144 may be deposited, for example, by chemical or physical vapor deposition. Preferably, the metal layer is deposited to a thickness of between about 100 Å and about 300 Å. After deposition of the metal layer 144, a thermal anneal process is performed to catalyze the reaction of the metal layer 144 and the silicon 120. Preferably, a rapid thermal aneal (RTA) is performed at a temperature of between about 650° C. and about 750° C. for between about 30 seconds and about 2 minutes.

Referring now to FIG. 7c, following the anneal, the excess or unreacted metal layer 144 is removed to reveal the metal silicide layer 148 that has formed in all of the exposed silicon surfaces. For example, the metal silicide layer 148 will form in source and drain regions 128 and on polysilicon gates 136. A large area of metal silicide 148 will form on the silicide test pad 100.

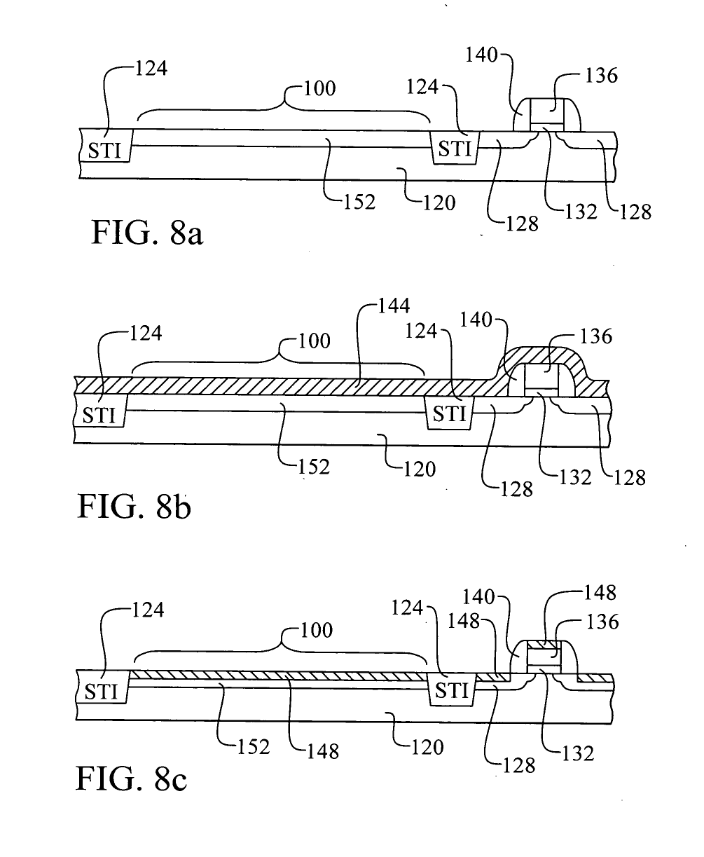

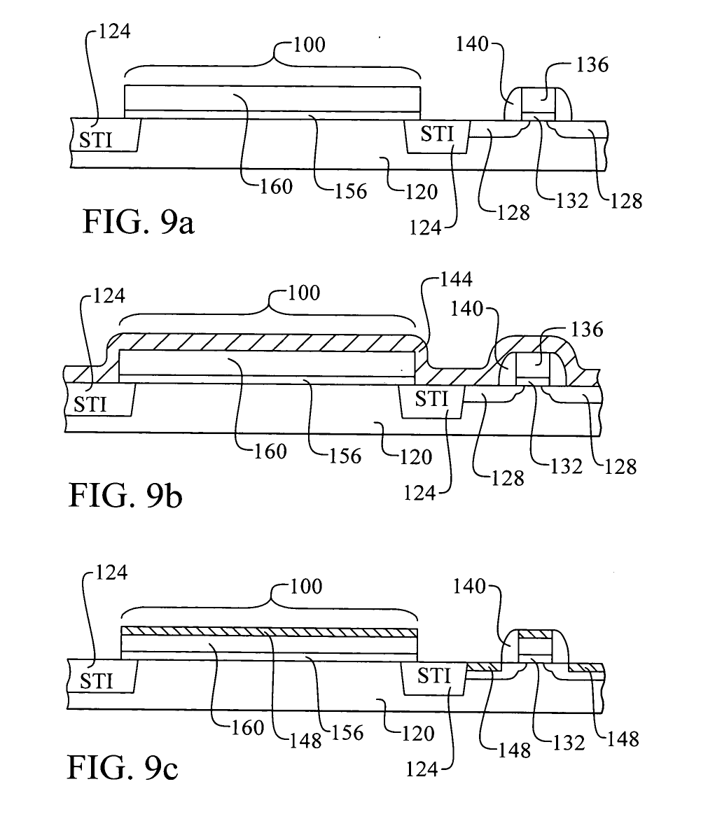

Referring now to FIGS. 8a-8c, as an alternative, the silicide test pad 100 may be a heavily doped region 152 in the silicon substrate 120. In this way, the silicide test pad 100 could match the doping of the source and drain regions 128 of the MOS devices. Otherwise, the method of formation of the metal silicide layer 148 is the same as shown in FIGS. 7a-7c. Referring now to FIGS. 9a-9c, as another alternative, the silicide test pad 100 may be a polysilicon layer 160. For example, the silicide test pad 100 may comprise a polysilicon layer 160 overlying an oxide layer 156 to mimic the MOS transistor gates 136 and 132. Alternatively, the silicide test pad 100 polysilicon layer 160 could be the same layer as the polysilicon gate 136. Again, the method of formation of the metal silicide layer 148 on the silicide test pad 100 is otherwise the same as in FIGS. 7a-7c.

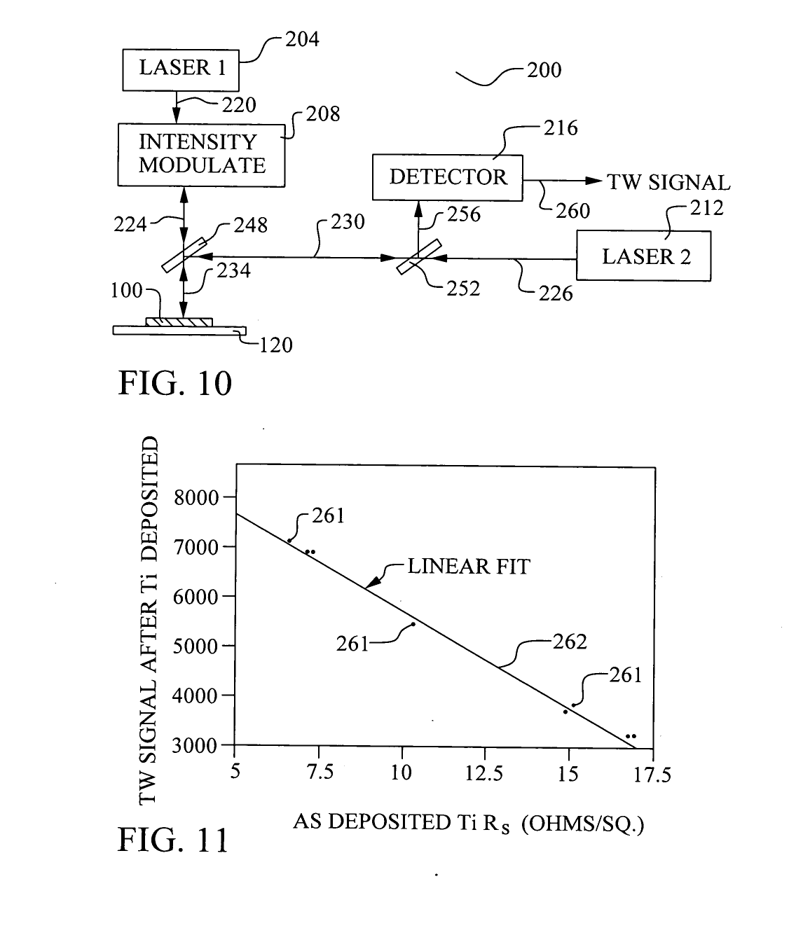

Once the metal silicide processing steps have been completed, the sheet resistance of the silicide test pad 100 is measured. Referring now to FIG. 10, the preferred embodiment of the measuring system 200 of the present invention is illustrated. The production wafer 120 is loaded into an optical inspection apparatus capable of generating a thermal wave signal TW 260. The system 200 preferably comprises a first laser beam 220 having a first wavelength. Preferably, this first laser beam 220 has a near infrared wavelength of about 790 nanometers. This first laser beam 220 is generated by a first laser 204. The first laser beam 220 is intensity modulated 208. In this configuration, the resulting modulated first laser beam 224 is designed to act as a pump laser or a heating laser when it is projected onto the silicide test pad 100 of the silicon wafer 120.

A second laser beam 226 is generated by a second laser 212. This second laser beam 226 is of a different wavelength than the first laser beam 220. Preferably, the second laser beam 226 comprises a visible light wavelength of about 670 nanometers. This second laser beam 226 is not intensity modulated and is designed to act as probe laser. The second laser beam 226 is routed through a first mirror 252 onto a dichroic mirror 248. The dichroic mirror 248 is designed to transmit the first laser beam 244 and to reflect the second laser beam 230 such that both the first and second laser beams 224 and 230 are projected 234 onto the silicide test pad 100 of the substrate 120.

The first beam component of the projected light 234 causes local heating of the silicide test pad 100. This heating is periodic due to the periodic nature of the intensity modulation. Further, this periodic heating is known in the art to propagate through the silicide film as a thermal wave. Such thermal waves share some mathematical properties with optical or acoustical waves but typically only travel a few wavelengths before dissipating. The second beam component of the projected light 234 detects the presence, magnitude, or phase of the induced thermal wave. As the thermal wave propagates in the silicide layer 100, the light reflectance and absorption properties of the silicide layer change. Therefore, the second beam component that is reflected back from the silicide layer 100 will contain thermal wave information encoded in the reflected light intensity and/or phase.

The reflected, combined light 234, interacts with the dichroic mirror 248. Again, the dichroic mirror 248 transmits the first beam 224 while reflecting the second beam 230 due to differences in wavelengths. In this way, the first beam 224, which is used for heating, is stripped away from the second beam 230, which carries the measurement information. When the returning second beam 230 interacts with the first mirror 252 in the return direction, it is reflected up to a detector 216. The detector 216 captures the energy of the reflected second beam 256 and generates a thermal wave (TW) intensity signal 260. The detector 216 may comprise, for example, an array of photo diodes, not shown, that can convert the photon energy of the returning second beam 256 into electrical signals.

It is found that the magnitude of this TW signal 260 corresponds to the sheet resistance of the silicide test pad 100. First, the TW intensity signal 260 was measured using the optical system 200. Next, the sheet resistance of the silicide test pad was measured by a direct probing method. Finally, the TW signal and sheet resistance data were analyzed. Referring now to FIG. 11, the TW signal is plotted on the Y-axis, and the probed sheet resistance is plotted on the X-axis. In this case, the data points 261 were obtained by measuring the test pad prior to the annealing step. That is, the data 261 is for the as deposited metal, in this case Ti. The data points 261 cover a range of sheet resistance from about 6 ohms/square to about 17.5 ohms/square. A linear fit to this data was calculated and resulted in the equation:
TW Signal=9687.0894−399.27979×Rₛ.
A statistical analysis was performed and an excellent correlation between the measured data and the linear fit was found.

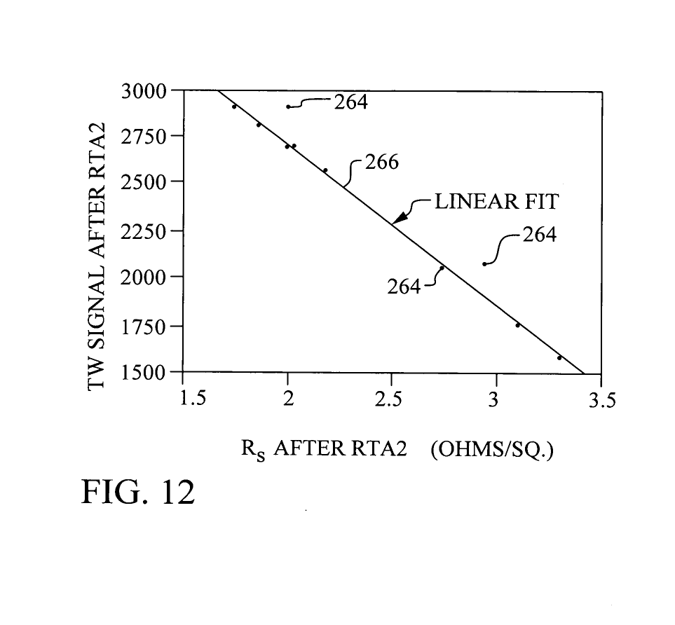

Referring now to FIG. 12, a similar analysis was performed on the test pad after the annealing step. Again, the TW signal is plotted on the Y-axis and the probed sheet resistance is plotted on the X-axis. The annealing operation reduces the sheet resistance such that the data points 264 cover a range of sheet resistance from about 1.7 ohms/square to about 3.4 ohms/square. A linear fit to this data was calculated and resulted in the equation:
TW Signal=4335.0412−813.87954×Rₛ.
A statistical analysis was again performed and an excellent correlation between the measured data and the linear fit was found.

As a result of this analysis, it is found that the sheet resistance Rₛ of the metal silicide layer can be calculated based on the optical system measurement. As another important feature of the present invention, the measured TW signal 260 is used to calculate a sheet resistance Rₛ value. This calculated sheet resistance Rₛ value is then plotted on a statistical process control (SPC) chart. Based on the standard theory of SPC that is known in the art, the sheet resistance Rₛ value is then used to assess the on-going status of the silicide process. Based on the current sheet resistance Rₛ value and on the previous series of values, the silicide process is determined to either be “in control” or “out of control”. Further, if the process is “out of control,” then the process is stopped until a root cause is determined.

As is shown in FIG. 11, the method may be used to measure the sheet resistance Rₛ value after the deposition of the metal layer but before the thermal annealing. This provides another location in the process flow at which to monitor the process and to apply SPC.

The advantages of the present invention may now be summarized. An effective and very manufacturable method to monitor a metal silicide process in an integrated circuit device is achieved. The method eliminates the need for the use of monitoring wafers. The method provides metal silicide sheet resistance data directly from production wafers. The sheet resistance measurement more accurately reflects processing results on the production wafers. The method of measurement does not lead to quality losses due to direct probing damage. The method of measurement can be easily incorporated into a statistical processing control (SPC) system.

As shown in the preferred embodiments, the novel method of the present invention provides an effective and manufacturable alternative to the prior art.

While the invention has been particularly shown and described with reference to the preferred embodiments thereof, it will be understood by those skilled in the art that various changes in form and details may be made without departing from the spirit and scope of the invention.

1. A method to monitor sheet resistance of a metal silicide layer in the manufacture of an integrated circuit device, said method comprising:
providing a metal silicide layer overlying an exposed silicon layer on a substrate;
generating a thermal wave intensity signal for said metal silicide layer by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal silicide layer; and
a detector to gather said second laser beam reflected from said metal silicide layer and to generate a thermal wave intensity signal based on said reflected second laser beam; and
calculating sheet resistance of said metal silicide layer by a linear equation based on said thermal wave intensity signal.

2. The method according to claim 1 wherein said metal silicide layer comprises titanium silicide, cobalt silicide, or nickel silicide.

3. The method according to claim 1 wherein said exposed silicon layer comprises a minimum surface area of about 2500 μm.

4. The method according to claim 1 wherein said exposed silicon layer comprises polysilicon.

5. The method according to claim 1 wherein said exposed silicon layer is doped.

6. The method according to claim 1 wherein said step of providing a metal silicide layer further comprises the steps of:
depositing a metal layer overlying said exposed silicon layer;
thermally annealing said metal layer to form said metal silicide layer; and
removing remaining said metal layer.

7. The method according to claim 6 further comprising:
generating a thermal wave intensity signal for said metal layer prior to said step of thermal annealing by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal layer; and
a detector to gather said second laser beam reflected from said metal layer and to generate a thermal wave intensity signal based on said reflected second laser beam; and
calculating sheet resistance of said metal layer by a linear equation based on said thermal wave intensity signal.

8. The method according to claim 1 further comprising plotting said sheet resistance of said metal silicide layer onto a statistical process control chart.

9. The method according to claim 8 wherein said statistical process control chart is used to start and stop said manufacturing based on control and out of control states.

10. A method to monitor sheet resistance of a metal silicide layer in the manufacture of an integrated circuit device, said method comprising:
providing a metal silicide layer overlying an exposed silicon layer on a substrate wherein said exposed silicon layer comprises a minimum surface area of about 2500 μm²;
generating a thermal wave intensity signal for said metal silicide layer by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal silicide layer; and
a detector to gather said second laser beam reflected from said metal silicide layer and to generate a thermal wave intensity signal based on said reflected second laser beam;
calculating sheet resistance of said metal silicide layer by a linear equation based on said thermal wave intensity signal; and
plotting said sheet resistance of said metal silicide layer onto a statistical process control chart.

11. The method according to claim 10 wherein said metal silicide layer comprises titanium silicide, cobalt silicide or nickel silicide.

12. The method according to claim 10 wherein said exposed silicon layer comprises polysilicon.

13. The method according to claim 10 wherein said exposed silicon layer is doped.

14. The method according to claim 10 wherein said step of providing a metal silicide layer further comprises the steps of:
depositing a metal layer overlying said exposed silicon layer;
thermally annealing said metal layer to form said metal silicide layer; and
removing remaining said metal layer.

15. The method according to claim 14 further comprising:
generating a thermal wave intensity signal for said metal layer prior to said step of thermal annealing by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal layer; and
a detector to gather said second laser beam reflected from said metal layer and to generate a thermal wave intensity signal based on said reflected second laser beam; and
calculating sheet resistance of said metal layer by a linear equation based on said thermal wave intensity signal.

16. The method according to claim 10 wherein said statistical process control chart is used to start and stop said manufacturing based on control and out of control states.

17. A method to monitor sheet resistance of a metal silicide layer in the manufacture of an integrated circuit device, said method comprising:
depositing a metal layer overlying an exposed silicon layer on a substrate wherein said exposed silicon layer comprises a minimum surface area of about 2500 μm²;
thermally annealing said metal layer to form a metal silicide layer; and
removing remaining said metal layer;
generating a thermal wave intensity signal for said metal silicide layer by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal silicide layer; and
a detector to gather said second laser beam reflected from said metal silicide layer and to generate a thermal wave intensity signal based on said reflected second laser beam;
calculating sheet resistance of said metal silicide layer by a linear equation based on said thermal wave intensity signal; and
plotting said sheet resistance of said metal silicide layer onto a statistical process control chart.

18. The method according to claim 17 wherein said exposed silicon layer comprises polysilicon.

19. The method according to claim 17 further comprising:
generating a thermal wave intensity signal for said metal layer prior to said step of thermal annealing by an optical measurement system comprising:
a first laser beam wherein said first laser beam is intensity modulated;
a second laser beam wherein said first and second laser beams comprise different wavelengths;
a dichroic mirror to combine said first and second laser beams and to project said first and second laser beams onto said metal layer; and
a detector to gather said second laser beam reflected from said metal layer and to generate a thermal wave intensity signal based on said reflected second laser beam; and
calculating sheet resistance of said metal layer by a linear equation based on said thermal wave intensity signal.

20. The method according to claim 17 wherein said statistical process control chart is used to start and stop said manufacturing based on control and out of control states.
